(19) United States
(12) Patent Application Publication
(10) Pub. No.: US 2023/0380411 A1
(43) Pub. Date: Nov. 30, 2023

(54) MOTORIZED WILDLIFE DECOY AND BATTERY SYSTEM

(71) Applicant: Tyler J. BASKFIELD, Denver, CO (US)

(72) Inventor: Tyler J. BASKFIELD, Denver, CO (US)

(21) Appl. No.: 18/203,869

(22) Filed: May 31, 2023

Related U.S. Application Data
(60) Provisional application No. 63/347,343, filed on May 31, 2022.

(51) Int. Cl. A01M 31/06; H05K 5/06; H05K 5/00; H01M 50/24; H01M 10/48

(52) U.S. Cl. CPC A01M 31/06; H05K 5/061; H01M 2220/20; H01M 50/24; H01M 10/488; H05K 5/0086

(57) ABSTRACT

A motorized wildlife decoy can be powered by an external power system that includes a completely enclosed or encapsulated battery that is connected to the decoy to power the drive motor(s). The power system is separate from the decoy body but can be electrically coupled to the decoy body. When coupled, the power system serves a dual purpose of providing power to the motors while acting as a ballast, or as an anchor, to anchor the motorized decoy to the bottom of a wetland, impoundment, field or other area that is being hunted.

### PRIORITY

This application claims the priority benefit of U.S. Provisional Application No. 63/347,343, filed on May 31, 2022, which is hereby incorporated herein by reference in its entirety.

### FIELD

The present invention relates generally to waterfowl decoys used for hunting and, more particularly, to waterfowl decoys that are motorized to mimic lifelike movement of waterfowl.

### BACKGROUND

Waterfowl hunting is a popular sport enjoyed by hundreds of thousands of individuals. The traditional style of waterfowl hunting is based on hunters attempting to lure waterfowl to fly within the effective range of the hunter's shotguns. The most common method for achieving this is for the hunter to place decoys resembling live waterfowl on the surface of a body of water, in a field or on the edge of a river, lake or impoundment, in close proximity to the hunter's location.

One of the major problems experienced by waterfowl hunters is the lack of motion from traditional style static waterfowl hunting decoys. Live waterfowl are not attracted to decoys that are motionless on a smooth water surface or on land. In fact, decoy spreads that have no movement can often spook wary waterfowl and hinder hunting success. Traditional decoys rely on wind for movement and waterfowl hunting often takes place on small impoundments, fields, or wetlands that need heavy winds to churn the surface of the water to move the decoys, or agitate or propel traditional dry land or field decoys.

It is common knowledge among waterfowl hunters that motion decoys, those exhibiting some form of animation that adds motion similar to waterfowl behaving naturally in their normal habitat, are more likely to attract waterfowl than are traditional static decoys. For example, U.S. Pat. Nos. 6,553,709, 8,997,394 and 11,083,189 each disclose a duck decoy that includes motorized features. U.S. Pat. Nos. 8,997,394 and 11,083,189 are both incorporated by reference herein in their entirety.

Motorized decoys are typically powered via batteries. Keeping batteries and power systems for motorized decoys protected, efficient, light, simple and as intuitive as possible is important because many hunters travel significant distances with large amounts of gear using different methods of travel. Hunters also tend to practice their craft in a wide variety of lighting (e.g., daylight and nighttime) and weather conditions (e.g., cold, snow, rain and other adverse weather conditions).

Batteries employing conventional lithium-ion chemistry may be compact, but they are very sensitive to heat, impacts, and will often fail with the slightest contact with water. Moreover, the contents of such batteries can be damaging to the environment if their contents are exposed. As a result, there is a continuing need to provide motorized decoys, and power supplies therefore, that have improved reliability and that better fit the need of hunters and the environment.

### SUMMARY

The present invention addresses the problems discussed above regarding motorized decoys. A motorized waterfowl decoy can be powered by an external power system that includes a completely enclosed, potted or encapsulated battery that is connected to the decoy to power its drive motor(s). The power system is separate from the decoy body but can be electrically coupled to the decoy body. When coupled, the power system serves a dual purpose of providing power to the motor(s) while acting as a ballast, or as an anchor, to anchor the motorized decoy to the bottom of a wetland or impoundment that is being hunted.

An encapsulated battery can also be used with traditional field decoys on dry land in order to keep batteries protected from elements, damage and provide a simpler and easier to use or efficient system

The power system can be easily removed for charging. The plug for the power system can be common to both the decoy body and a charging device so that the plug can mate commonly with both devices.

In one example embodiment, a motorized wildlife decoy system can comprise a decoy body, a motor provided to the decoy body such that the motor imparts movement to at least a portion of the motorized wildlife decoy, and an external power system that can be coupled to the decoy body to supply power to operate the motor. The external power system can include a battery that is sealed against moisture intrusion and a conduit. A proximal end of the conduit comprises a plug and a distal end of the conduit is electrically coupled to the battery.

The decoy body can include an electrical port to which the plug mates. The plug can be configured as a male protrusion, and the port can be configured as a female recess shaped to securely engage the male plug. The plug and the recess can be threaded.

The decoy body can include a waterproof gasket through which the plug and a portion of the conduit can pass to an interior of the decoy body without water intrusion.

The motorized wildlife decoy can resemble a waterfowl or other types of wildlife, such as turkey, big game species, predator species and any other type of wildlife pursued by hunters with decoys. The motorized wildlife decoy can be buoyant such that it floats on a surface of a body of water.

The battery can be sealed against moisture intrusion by being disposed within a sealed enclosure, by being encapsulated by a coating of protective outer material, by being potted, or by being over molded with an environmentally-friendly material, such as a plant-based fatty acid material, at a temperature sufficiently low to avoid damaging the battery . The protective outer material can be one or more of a plastic, epoxy, polymer, resin, urethane, silicone or rubber material that is molded around the battery

The battery can include a battery monitor circuit and/or a charging circuit. The battery can include a visual indicator of charge status. The battery can include a flange, and the flange can define an aperture therethrough to allow for a ballast weight to be attached to the external power system. The battery can include a ballast weight.

An external power system in another example can be coupled to the decoy body to supply power to operate a motor that is provided to the decoy body. The external power system can include a battery that is sealed against moisture intrusion and a conduit. A proximal end of the conduit can comprise a plug and a distal end of the conduit can be electrically coupled to the battery. The battery can be sealed against moisture intrusion by being disposed within a sealed enclosure, by being encapsulated by a coating of protective outer material, by being potted, and by being over molded with an environmentally-friendly material, such as a plant-based fatty acid material, at a temperature sufficiently low to avoid damaging the battery.

The above summary of the invention is not intended to describe each illustrated embodiment or every implementation of the invention. The figures in the detailed description that follow more particularly exemplify these embodiments.

### BRIEF DESCRIPTION OF THE DRAWINGS

The invention may be more completely understood in consideration of the following detailed description of various embodiments of the invention in connection with the accompanying drawings.

FIG. 1 is a side view diagram of a motorized decoy coupled to a power system in accordance with embodiments of the present invention.

FIG. 2 is a perspective view of a power system for motorized decoys in accordance with embodiments of the present invention.

While the invention is amenable to various modifications and alternative forms, specifics thereof have been shown by way of example in the drawings and will be described in detail. It should be understood, however, that the intention is not to limit the invention to the particular embodiments described. On the contrary, the invention is to cover all modifications, equivalents, and alternatives falling within the spirit and scope of the invention as defined by the appended claims. For illustrative purposes, hatching or shading in the figures is provided to demonstrate sealed portions and/or integrated devices for the package.

### DETAILED DESCRIPTION

In the following descriptions, the present invention will be explained with reference to various example embodiments; nevertheless, these embodiments are not intended to limit the present invention to any specific example, environment, application, or particular implementation described herein. Therefore, descriptions of these example embodiments are only provided for purpose of illustration rather than to limit the present invention. It is understood that the features mentioned hereinbefore and those to be commented on hereinafter may be used not only in the specified combinations, but also in other combinations or in isolation, without departing from the scope of the present invention.

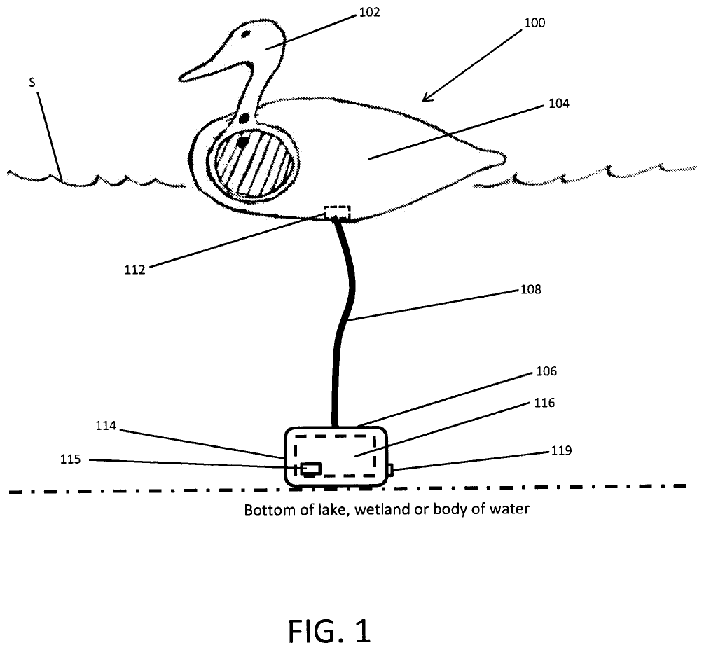

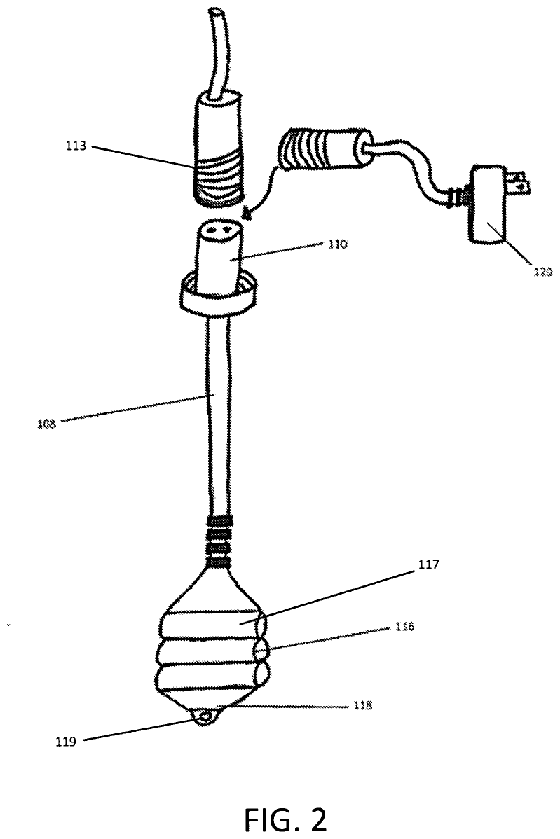

Referring to FIGS. 1 and 2, a waterfowl decoy device 100 is shown floating along the surface (S) of a lake, wetland or other body of water. The decoy 100 generally comprises a head portion 102 and a body portion 104. The body 104 includes one or more motors to impart movement to the head 102 and/or other portions of the decoy device 100. The incorporated U.S. Pat. Nos. 8,997,394 and 11,083,189 each disclose specific details of motorized waterfowl decoys that can be adapted to the external power system 106 described herein. The present decoy device 100 can also be configured as a dryland or field decoy. The present decoy device 100 can also be configured as other types of wildlife, such as turkey, big game species, predator species and any other type of wildlife pursued by hunters with decoys.

An external power system 106 is coupled to the decoy body 104 via an electrical conduit 108. The distal end of the conduit 108 terminates in a plug 110. The decoy body 104 includes an electrical port 112 to which the plug 110 mates. The plug 110 is configured as a male protrusion, and the port 112 is configured as a female recess shaped to securely engage the male plug 110. The male and female configurations can also be configured in reverse in alternative embodiments. The plug and recess can be threaded, ribbed, or a locking collar provided in order to enhance the securing action.

Alternatively, as shown in FIG. 2, the port 112 is embodied as a waterproof gasket 113 or closure through which the conduit 108 can pass to an interior of the decoy body 104. The electrical connection can then be made inside of the decoy body 104 without water intrusion.

Referring to FIG. 1, the power system 106 in certain embodiments comprises a sealed enclosure 114 containing the battery 116 (which may comprise one or more battery cells). The battery 116 is electrically coupled to the opposing (proximal) end of the conduit 108. The enclosure 114 is sealed such that the battery 116 will not be exposed to water even when the enclosure 114 is submerged underwater for many hours. This waterproof feature is preferably effective to a reasonable depth (e.g. 10 feet, 20 feet, etc.) that the enclosure 114 will experience when deployed in a lake, wetland or other body of water. The enclosure 114 also protects the battery when used with decoys in dryland or in field hunting applications.

The battery 116 can be a lithium-based chemistry battery or other battery chemistry type. The battery 116 can comprise one or more cells to achieve any desired voltage and capacity. The battery 116 also may comprise a battery monitor circuit and/or a charging circuit 115. The battery monitor circuit and/or a charging circuit 115 can include one or more microprocessor and/or one or more diodes. A charge status indicator 119 such as a red/green LED can be provided so that the user can visually determine a charge state of the battery 116.

In certain embodiments, the enclosure 114 can be formed of a plastic material and/or rubber material. In one example, the enclosure 114 comprises a two-piece plastic clamshell. A rubber gasket is provided along the mating edges of the clamshell portions to form the watertight seal. Silicone or other sealant types can be applied to ensure that the enclosure 114 is sufficiently secured together and is watertight to the desired depth.

In an alternative embodiment, referring to FIG. 2, the battery 116 is encapsulated by a protective outer material coating 117 (versus contained within an enclosure) to form an encapsulated power system 106. The outer protective material forming the coating 117 can be a plastic or rubber material that is molded around the battery 116 and at least a portion of the conduit 108. Additional coating materials may include epoxy, polymer, resin, urethane, silicone, potting compound, and or combinations of multiple different materials.

In a further alternative, the outer protective material can be an environmentally friendly material which is molded at a sufficiently low temperature to allow for the battery 116 and its circuit board(s) to be completely over molded or molded around with the protective material without overheating, burning, allowing contact with moisture or melting the battery 116 or its controlling circuit board.

A suitable material for encapsulating the battery 116 and its circuit components via a molding operation is made from the fatty acids of plants, rather than being plastic. Such material and the corresponding manufacturing process are more environmentally friendly than conventional plastic molding materials and processes. The outer protective material can be poured over the battery in a mold and allowed to harden. Other alternative encapsulating materials can be utilized as well.

In a further alternative, the battery and its electronics are potted. For example, an epoxy or urethane material is used to completely cover the battery assembly to exclude moisture from reaching the battery or its electronic components.

A further advantage of the present invention is that lead weights are not needed for waterfowl decoys since the external power system 106 can function as a ballast. Lead weights are commonly provided to decoys in order to anchor the decoys in their intended location because strong currents, wind or other conditions would undesirably move the decoys from their set locations. Lead is extraordinarily detrimental to the environment and to wildlife. The present invention allows the enclosed or encapsulated external power system 106 to act as an anchor or ballast. Thus the lead is not needed.

In use, the power conduit 108 is connected to the decoy 100 via a waterproof plug or connector 110. Once attached, the battery 116 located at the opposing end of the conduit 108 would then supply all power needed by the motorized decoy 100. The plugging in and removal of the connector 110 can function as the on/off switch for the decoy 100. The decoy 100 is then deployed in the wetland or lake as desired by the user. The battery end of the power system 106 sinks to the bottom of the lake or wetland to act as the anchor for the decoy 100. In dryland and field applications, the power system 106 keeps the battery protected from the environment and acts as a ballast for limiting movement of the decoy and restricting or enhancing its movement in a way that keeps the decoy's movement realistic.

After the decoy 100 is retrieved from its deployed position, the user removes the connector or plug 110 from the decoy to disconnect the power system 106. The user can recharge the battery 116 in the power system 106 by plugging the connector/plug 110 into a battery charger 120.

The retention force of the plug or connector 110 into the decoy body 104 should be sufficient to prevent disconnection during deployed usage. A locking clip or threaded plug can be used to enhance the security of the connection.

A flange 118 can be formed or provided to the battery enclosure 114 or encapsulated battery 116. The flange 118 can also define at least one aperture 119. The aperture 119 in the flange 118 can be used to attach cords, ropes, lines or other items to the battery end of the power system 106.

Additional weights can be attached to the conduit 108 and/or the battery enclosure 114 as may be desired by the user. The weights can be attached to the flange 118 of the battery portion 116.

Additional weights can be added inside of the enclosure 114 or into the encapsulation to increase the weight of the battery end of the power system 106.

Additional accessories can be provided that can be powered by the power system 106. For example, a light or lantern can be powered by the power system 106. The light or lantern has a plug port that is configured to accept the plug or connector of the power system.

An adaptor (or multiple adaptors) can be provided to allow the power system 106 to plug into other accessories, such as lights, lanterns, radios, etc.

In one example embodiment, a motorized waterfowl decoy 100 is provided as a system or in a kit along with the power system 104. A charger, plug adaptor and/or other accessories can also be included in the kit and form the system.

The present invention may be embodied in other specific forms without departing from the spirit or essential attributes thereof, and it is, therefore, desired that the present embodiment be considered in all respects as illustrative and not restrictive. Those skilled in the art may recognize other equivalents to the specific embodiment described herein which equivalents are intended to be encompassed by the claims attached hereto.

For purposes of interpreting the claims for the present invention, it is expressly intended that the provisions of Section 112, sixth paragraph of 35 U.S.C. are not to be invoked unless the specific terms “means for” or “step for” are recited in a claim.

What is claimed is:

1. A motorized wildlife decoy system, comprising:
a decoy body;
a motor provided to the decoy body such that the motor imparts movement to at least a portion of the motorized wildlife decoy;
an external power system that can be coupled to the decoy body to supply power to operate the motor, the external power system comprising:
a battery that is sealed against moisture intrusion; and
a conduit, wherein a proximal end of the conduit comprises a plug and a distal end of the conduit is electrically coupled to the battery.

2. The motorized wildlife decoy system of claim 1, wherein the decoy body includes an electrical port to which the plug mates.

3. The motorized wildlife decoy system of claim 2, wherein the plug is configured as a male protrusion, and the port is configured as a female recess shaped to securely engage the male plug.

4. The motorized wildlife decoy system of claim 2, wherein the plug and recess are threaded.

5. The motorized wildlife decoy system of claim 1, wherein the decoy body includes a waterproof gasket through which the plug and a portion of the conduit can pass to an interior of the decoy body without water intrusion.

6. The motorized wildlife decoy system of claim 1, wherein the motorized wildlife decoy resembles a waterfowl.

7. The motorized wildlife decoy system of claim 1, wherein the motorized wildlife decoy is buoyant such that the motorized wildlife decoy floats on a surface of a body of water.

8. The motorized wildlife decoy system of claim 1, wherein the battery is sealed against moisture intrusion by being disposed within a sealed enclosure.

9. The motorized wildlife decoy system of claim 1, wherein the battery includes a battery monitor circuit and/or a charging circuit.

10. The motorized wildlife decoy system of claim 1, wherein the battery includes a visual indicator of charge status.

11. The motorized wildlife decoy system of claim 1, wherein the battery is sealed against moisture intrusion by being encapsulated by a coating of protective outer material.

12. The motorized wildlife decoy system of claim 11, wherein the protective outer material is one or more of a plastic, epoxy, polymer, resin, urethane, silicone or rubber material that is molded around the battery.

13. The motorized wildlife decoy system of claim 1, wherein the battery is sealed against moisture intrusion by being potted.

14. The motorized wildlife decoy system of claim 1, wherein the battery is sealed against moisture intrusion by being over molded with a plant-based fatty acid material at a temperature sufficiently low to avoid damaging the battery.

15. The motorized wildlife decoy system of claim 1, wherein the battery includes a flange, and wherein the flange defines an aperture therethrough to allow for a ballast weight to be attached to the external power system.

16. The motorized wildlife decoy system of claim 1, wherein the battery includes a ballast weight.

17. An external power system that can be coupled to the decoy body to supply power to operate a motor that is provided to the decoy body, the external power system comprising:
a battery that is sealed against moisture intrusion; and
a conduit, wherein a proximal end of the conduit comprises a plug and a distal end of the conduit is electrically coupled to the battery.

18. The external power system of claim 17, wherein the battery is sealed against moisture intrusion by being disposed within a sealed enclosure.

19. The external power system of claim 17, wherein the battery is sealed against moisture intrusion by being encapsulated by a coating of protective outer material.

20. The external power system of claim 17, wherein the battery is sealed against moisture intrusion by being over molded with a plant-based fatty acid material at a temperature sufficiently low to avoid damaging the battery.
